(19) United States
(12) Patent Application Publication
(10) Pub. No.: US 2021/0316529 A1
(43) Pub. Date: Oct. 14, 2021

(54) STRETCHABLE SUBSTRATE AND FABRICATING METHOD THEREFOR

(71) Applicant: SHENZHEN ROYOLE TECHNOLOGIES CO., LTD., Shenzhen (CN)

(72) Inventor: He Li, Shenzhen (CN)

(21) Appl. No.: 17/358,359

(22) Filed: Jun. 25, 2021

Related U.S. Application Data
(63) Continuation of application No. PCT/CN2018/124922, filed on Dec. 28, 2018.

(51) Int. Cl. B32B 7/022; B29C 45/16; B32B 25/14

(52) U.S. Cl. CPC B32B 7/022; H01L 23/145; B32B 25/14; B29C 45/16

(57) ABSTRACT

The embodiments of the present disclosure disclose a stretchable substrate and a fabricating method therefor. The stretchable substrate includes at least two regions having different stretch ratios. Any two adjacent regions having different stretch ratios include at least one same material. In the stretchable substrate of the present disclosure, because any two adjacent regions include at least one same material, a mechanical property difference between the adjacent regions is reduced, and stretch notches, shifts and other problems do not easily occur.

### CROSS-REFERENCE TO RELATED APPLICATION

This application is a continuation of International Disclosure No. PCT/CN2018/124922, filed on Dec. 28, 2018. The disclosures of the aforementioned disclosures are hereby incorporated by reference in their entireties.

### TECHNICAL FIELD

The present disclosure relates to the field of stretchable substrates, and in particular, to a stretchable substrate and a fabricating method therefor.

### BACKGROUND

Currently, stretchable sensing devices gradually draw people's attention. However, there are corresponding defects in substrates of existing stretchable sensing devices. For example, during stretching of a full-region stretchable substrate, stretch deformation may occur on the entire region of the substrate. Not only the need of the stretchability of lines in the region is relatively high, but also it is not conducive to placement of external rigid components.

During stretching of a partially-hardened stretchable substrate, there is a remarkable mechanical property difference at a boundary position between a rigid region and a stretchable region, and stretch notches, shifts and even breaks easily appear.

### SUMMARY

The present disclosure proposes a novel stretchable substrate and a fabricating method therefor.

An implementation solution of the present disclosure provides a stretchable substrate. The stretchable substrate includes at least two regions having different stretch ratios. Any two adjacent regions having different stretch ratios include at least one same material.

In some embodiments, the same material is continuously distributed in the regions having different stretch ratios.

In some embodiments, the same material is continuously distributed at a boundary between the adjacent regions having different stretch ratios.

In some embodiments, the regions having different stretch ratios are consistent in tensile strength.

In some embodiments, the same material is a stretchable material.

In some embodiments, the same material has different weight proportions in the two adjacent regions having different stretch ratios.

In some embodiments, the stretchable substrate includes a first material and a second material, and the first material and the second material are mixed in the regions having different stretch ratios.

In some embodiments, in the regions having different stretch ratios, a higher weight proportion of the first material indicates a lower weight proportion of the second material.

In some embodiments, the first material is a stretchable material, and the second material is an unstretchable material.

In some embodiments, the first material is a first stretchable material, the second material is a second stretchable material, and stretch ratios of the first stretchable material and the second stretchable material are different.

In some embodiments, the first stretchable material is selected from at least one of vinyl polysiloxane and polydimethylsiloxane, a main chain of vinyl polysiloxane is a silicon-oxygen chain, and a side chain of vinyl polysiloxane has a vinyl group and/or a vinyl group-terminated polymer.

In some embodiments, the second stretchable material is selected from at least one of polyurethane, a styrene-butadiene-styrene block copolymer, a styrene-ethylene-butene-styrene block copolymer, poly(butylneadipate-co-terephthalate) and nanoparticle-doped vinyl polysiloxane, a main chain of vinyl polysiloxane is a silicon-oxygen chain, and a side chain of vinyl polysiloxane has a vinyl group and/or a vinyl group-terminated polymer.

In some embodiments, the first stretchable material is polydimethylsiloxane, the second stretchable material is nanoparticle-doped vinyl polysiloxane, a main chain of vinyl polysiloxane is a silicon-oxygen chain, and a side chain of vinyl polysiloxane has a vinyl group and/or a vinyl group-terminated polymer.

In some embodiments, a mass ratio of a raw material of polydimethylsiloxane to a raw material of nanoparticle-doped vinyl polysiloxane is 1:(0.05-2).

In some embodiments, the stretchable substrate is a one-dimensional stepped stretchable material, and the regions having different stretch ratios are symmetrically distributed on two sides of a region having the highest or lowest stretch ratio.

In some embodiments, stretch ratios of other regions gradually decrease from the region having the highest stretch ratio to two sides, or stretch ratios of other regions gradually increase from the region having the lowest stretch ratio to two sides.

In some embodiments, the stretchable substrate is a two-dimensional stepped stretchable material, and a region having a lower stretch ratio is surrounded by a region having a higher stretch ratio.

In some embodiments, at least one of the regions having different stretch ratios includes an unstretchable material.

In some embodiments, the unstretchable material is selected from inorganic oxide particles.

In some embodiments, the inorganic oxide is selected from at least one of silicon dioxide, aluminum oxide, hafnia, zirconium dioxide, titanium dioxide and calcium oxide.

In some embodiments, the unstretchable material is a sheet-like material, and the sheet-like material is wrapped by the stretchable material.

Another implementation solution of the present disclosure provides a fabricating method for a stretchable substrate. The stretchable substrate includes at least two regions having different stretch ratios, where any two adjacent regions having different stretch ratios include at least one same material. The method includes:

injecting raw materials for regions having different stretch ratios into corresponding regions in a mold, where mass ratios of one same material contained in the raw materials for the regions having different stretch ratios are different; and solidifying the raw materials in each of the regions.

In some embodiments, the method further includes: mixing the raw materials for each of the regions in advance before injecting the raw materials for the regions having different stretch ratios into the corresponding regions in the mold.

In some embodiments, different raw materials conveyed by different conveying paths are mixed in an injection head before being injected into the corresponding regions.

In some embodiments, different pressures are exerted on the different conveying paths.

In some embodiments, inner diameters of the different conveying paths are different.

In some embodiments, before the raw materials for the different regions are injected into the corresponding regions in the mold, partition plates are disposed between the regions. The partition plates are removed after the injection of all the raw materials and before the solidification.

In the stretchable substrate of the embodiments of the present disclosure, because any two adjacent regions include at least one same material, a mechanical property difference between the regions is reduced, and stretch notches, shifts and other problems do not easily occur at a boundary between adjacent regions.

### BRIEF DESCRIPTION OF DRAWINGS

To describe the technical solutions in the present disclosure more clearly, the following briefly describes the accompanying drawings required for describing the embodiments. It should be understand that the following accompanying drawings show merely some embodiments of the present disclosure and should not be construed as limiting the protection scope of the present disclosure.

FIG. 1 is a schematic diagram illustrating a stretchable substrate example according to the present disclosure;

FIG. 2 is a schematic diagram illustrating another stretchable substrate example according to the present disclosure;

FIG. 3 is a schematic diagram illustrating still another stretchable substrate example according to the present disclosure;

FIG. 4 is a schematic diagram illustrating tensile break performance tests on materials in three regions of a stretchable material example according to the present disclosure;

FIG. 5 is a schematic diagram illustrating a fabricating method for a stretchable substrate according to the present disclosure;

FIG. 6 is a schematic diagram illustrating another fabricating method for a stretchable substrate according to the present disclosure; and

FIG. 7 is a schematic diagram illustrating still another fabricating method for a stretchable substrate according to the present disclosure.

### DESCRIPTION OF EMBODIMENTS

The following clearly and completely describes the technical solutions in the embodiments of the present disclosure with reference to the accompanying drawings in the embodiments of the present disclosure. Apparently, the described embodiments are merely some rather than all embodiments of the present disclosure.

In the following, the terms “comprising”, “having”, and their cognates used in various embodiments of the present disclosure are intended to refer only to a particular feature, number, step, operation, element, component, or a combination thereof, and should not to be construed as excluding first the presence of one or more other features, numbers, steps, operations, elements, components or a combination thereof or the possibility of adding one or more features, numbers, steps, operations, elements, components or a combination thereof.

In the description of this specification, reference to the description of the terms “one embodiment”, “some embodiments”, “example”, “specific example”, “some examples”, etc. means that particular features, structures, materials, or characteristics described with reference to the embodiments or examples are included in at least one embodiment or example of the present disclosure. In this specification, schematic representations of the above terms do not necessarily refer to the same embodiment or example. Furthermore, the particular features, structures, materials, or characteristics described may be combined in a suitable manner in any one or more embodiments or examples.

Unless otherwise specified, all terms (including technical and scientific terms) used herein have the same meanings as those usually understood by a person of ordinary skill in the art for the various embodiments of the present invention. The terms (such as those defined in commonly used dictionaries) will be interpreted as having meanings that are the same as the contextual meanings in the related technologies and will not be interpreted as having idealized or overly formal meanings unless expressly specified in the various embodiments of the present disclosure.

An implementation solution of the present disclosure provides a stretchable substrate. The stretchable substrate includes at least two regions having different stretch ratios. Any two adjacent regions having different stretch ratios include at least one same material. For example, if the stretchable substrate includes a first region, a second region and a third region, the first region and the second region may both include at least material A, and the second region and the third region may both include at least material B. Material A and material B may be the same material or different materials. Similarly, if the stretchable substrate includes four or more regions, the same material contained in two adjacent regions may be the same as or different from that contained in the other two adjacent regions. The same material may have the same or different weight proportions in the two adjacent regions. For example, two adjacent regions include material A and material B. In this case, material A and material B may have different weight proportions in the two regions, so as to achieve different stretch ratios. In addition, for example, if a first region in two adjacent regions includes materials A, B and C and a second region includes materials A, D and E, the two regions may have the same content of material A, and stretch ratios of the two regions may be adjusted through materials B and C and materials D and E.

In some embodiments, the same material is continuously distributed in the regions having different stretch ratios. For example, taking the stretchable substrate including the first region, the second region and the third region as an example, material A is continuously distributed in the first region and the second region, and material B is continuously distributed in the second region and the third region. In some embodiments, the same material is continuously distributed at a boundary between the adjacent regions having different stretch ratios. For example, material A is continuously distributed at a boundary between the first region and the second region, and material B is continuously distributed at a boundary between the second region and the third region.

In some embodiments, the regions having different stretch ratios are consistent in tensile strength. For example, the first region, the second region and the third region all include materials A and B, but proportions of materials A and B are different in the regions. In this case, three regions having different stretch ratios but substantially consistent tensile strength can be formed.

Preferably, the same material is a stretchable material. In some embodiments, the stretchable substrate includes a first material and a second material, and the first material and the second material are mixed in the regions having different stretch ratios. In some embodiments, in the regions having different stretch ratios, a higher weight proportion of the first material indicates a lower weight proportion of the second material.

In some embodiments, the first material is a stretchable material, and the second material is an unstretchable material. In some embodiments, the first material is a first stretchable material, the second material is a second stretchable material, and stretch ratios of the first stretchable material and the second stretchable material are different.

In some embodiments, the regions include at least one same stretchable material, and the same stretchable material is continuously distributed in the regions.

The stretchable substrate in the embodiment of the present disclosure may be a sheet-like material, and in particular, is suited as a stretchable substrate for a stretchable sensor. Because stretch ratios are different in the regions described above, different elastic deformations are generated during stretching between the regions arranged abreast.

The regions having different stretch ratios described above are formed by mixing and solidifying different raw materials. To reduce a mechanical property difference between the regions and reduce stretch notches, shifts and other problems, the regions in some embodiments of the present disclosure include at least one same stretchable material, and the same stretchable material is continuously distributed in the regions.

In particular, the stretchable substrate described above is suited as a stretchable substrate for arrangement of circuits and circuit components. Through a substrate designed with stepped and gradually varied distribution of stretch ratios, regions having different stretch ratios may be obtained on the same stretchable substrate. Therefore, stretchability of stretchable devices can be improved by optimizing a circuit layout. For example, a region for dense circuits or components is placed in a region having a low stretch ratio to reduce failures caused by stretching the dense circuits, and reduce difficulty in mounting components and selecting component models (currently, there are almost no stretchable resistors, capacitors, ICs or other components).

There are multiple distribution modes for the regions having different stretch ratios in the present disclosure, e.g., a one-dimensional stepped distribution mode, or a two-dimensional stepped distribution mode.

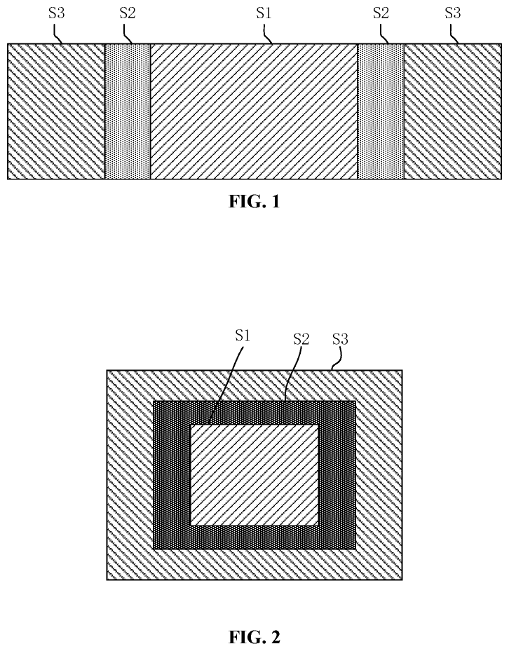

In the one-dimensional stepped distribution mode, the regions having different stretch ratios are disposed in a linear direction. For example, stretch ratios may gradually increase and then gradually decrease in one direction. Alternatively, stretch ratios may gradually decrease and then gradually increase in one direction. Still alternatively, stretch ratios may gradually increase or decrease in one direction. Further alternatively, the regions having high stretch ratios and the regions having low stretch ratios may be staggered at intervals. For example, for a one-dimensional stepped stretchable material in FIG. 1, stretch ratios of regions S1, S2 and S3 may gradually decrease. Or, the stretch ratios of regions S1, S2 and S3 may gradually increase. In the one-dimensional stepped stretchable material, the regions having different stretch ratios are symmetrically distributed on two sides of region S1 having the highest or lowest stretch ratio.

For example, when the stretch ratios of regions S1, S2 and S3 in FIG. 1 gradually decrease, region S1 having the highest stretch ratio is located in the middle, and regions S2 and S3 whose stretch ratios gradually decrease are symmetrically distributed on the two sides of region S1. In this case, region S1 has the highest stretch ratio and the largest stretch deformation, and serves as a main stretchable region. Region S3 has the lowest stretch ratio and the smallest stretch deformation, and serves as a main unstretchable region. Region S2 has an intermediate stretch ratio and a stretch deformation between those of regions S1 and S3, and serves as a transitional region.

Although FIG. 1 only shows the regions having three stretch ratios, regions having more stretch ratios may also be disposed as desired, e.g., regions having four or five stretch ratios may be disposed. Disposition of more regions having different stretch ratios indicates a smaller difference between the stretch ratios of the regions. Therefore, a property difference between the regions is gradually decreased, which further reduces the probability of stretch notches, shifts and other problems. Certainly, regions having only two different stretch ratios may alternatively be disposed. In the example of FIG. 1, the regions having different stretch ratios have different areas, or may have the same area. Moreover, the regions having the same stretch ratio (e.g., two regions S2 or two regions S3) may alternatively have different areas as desired. This is the same in other examples.

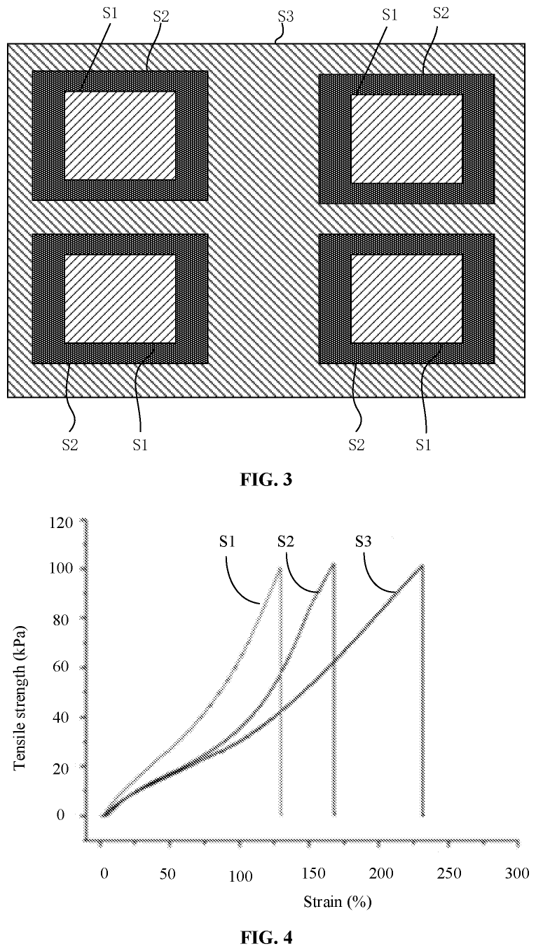

In the two-dimensional stepped arrangement, the regions having different stretch ratios may be disposed in both a transverse direction and a longitudinal direction. For example, referring to FIG. 2, stretch ratios of regions S1, S2 and S3 gradually increase. Certainly, only regions having two stretch ratios or regions having more than three different stretch ratios may be disposed.

In FIG. 2, the two-dimensional stepped stretchable material forms an enclosed structure, i.e., a region having a lower stretch ratio is surrounded by a region having a higher stretch ratio, and the stretch ratios gradually increase from inside out. As a preferred mode for the two-dimensional stepped stretchable material, stretch ratios of regions gradually increase from inside to outside.

Certainly, other structures may alternatively be used based on specific needs, e.g., a stretch ratio of region S2 is the highest, and stretch ratios of regions S1 and S3 are lower than that of region S2. Or, the stretch ratios of regions S1, S2 and S3 may be gradually decreased as desired.

In addition, some other structures different from the structure in FIG. 2 may alternatively be adopted as desired, e.g., region S2 may not be circular, but is located only on two sides or one side of region S1. In addition, multiple regions S1 and multiple regions S2 may be arranged inside the region S3. For example, as shown in FIG. 3, regions S1 and regions S2 are distributed inside region S3 as a matrix. Such practice is applicable to a more complex circuit layout.

In some embodiments of the present disclosure, regions preferably include at least one same stretchable material, and the same stretchable material is continuously distributed in the regions. When the regions are stretched and broken under the same force, stretch deformations of the regions are different, i.e., elasticity moduli are different. For example, all regions include the same elastic rubber, some regions include inorganic oxide particles serving as an unstretchable material, and some regions do not include the inorganic oxide particles. The two different types of regions have different stretch ratios. Moreover, hardness of the regions including the inorganic oxide particles increases. Certainly, all the regions may alternatively include inorganic oxide particles. Different regions include different content, types and/or particle sizes of oxide. Therefore, hardness and stretch ratios of the different regions are also different.

The inorganic oxide particles can be selected from at least one of silicon dioxide, aluminum oxide, hafnia, zirconium dioxide, titanium dioxide and calcium oxide. The inorganic oxide particles can increase the hardness but reduce the stretch ratios of the regions. The inorganic oxides may also be added to each region, and can change a stretch ratio by changing type, amount, and particle size of the inorganic oxide addition. The inorganic oxide particles may be micron-scale particles or even nano-scale particles. The nanoparticles are properly modified and then added to a stretchable material, such that tensile strength and a stretch ratio of the material can be improved.

The unstretchable material may be a sheet-like material, and the sheet-like material is wrapped by the stretchable material. An external rigid component may be disposed in a corresponding region of the sheet-like unstretchable material. Because the sheet-like unstretchable material is wrapped by the stretchable material, stretch notches or even breaks do not easily occur. The sheet-like unstretchable material may be, e.g., cloth and rigid plastics.

The stretchable material is continuously distributed, and the regions include at least one same material. Therefore, a bonding force between different regions is enhanced, thereby reducing a risk of notches at a boundary between a region having a low stretch ratio and a region having a high stretch ratio. When the sheet-like material is used as an unstretchable material, a material with an elongation rate at break (tested in accordance with National Standard GB/T 1040) less than 5% is called an unstretchable material in the present disclosure. Accordingly, a material with an elongation rate at break greater than or equal to 5% is called a stretchable material. A stretch ratio of at least one region in the stretchable substrate of the present disclosure is greater than or equal to 5%.

In some embodiments of the present disclosure, each region includes at least two main materials. The at least two main materials are both continuously distributed in the regions. At least one main material is a stretchable material, and the other one or more main materials may be stretchable materials or unstretchable materials. The main materials herein refer to materials capable of providing stretchability and/or improving strength for the substrate, rather than auxiliary materials such as a plasticizer, a coupling agent and an initiator. In other words, the stretchable material or the unstretchable material does not include these additives. The stretchable material may be, e.g., polyurethane, a styrene-butadiene-styrene (SBS) block copolymer, a styrene-ethylene-butene-styrene (SEBS) block copolymer, poly(butylneadipate-co-terephthalate) (PBAT) and silicone rubber. The silicone rubber may be, e.g., vinyl polysiloxane, nanoparticle-doped vinyl polysiloxane and polydimethylsiloxane. A main chain of vinyl polysiloxane is a silicon-oxygen chain, and a side chain of vinyl polysiloxane has a vinyl group and/or a vinyl group-terminated polymer. The unstretchable material may be, e.g., phenolic resin, polystyrene and polymethylmethacrylate.

Each region may include two groups of stretchable materials. Each group of stretchable materials may include multiple stretchable materials. Stretch ratios of one group of stretchable materials are lower than those of the other group of stretchable materials. A stretchable material having a lower stretch ratio may be selected from at least one of vinyl polysiloxane and polydimethylsiloxane. A stretchable material having a higher stretch ratio may be selected from at least one of nanoparticle-doped vinyl polysiloxane, polyurethane, a styrene-butadiene-styrene block copolymer, a styrene-ethylene-butene-styrene block copolymer and poly(butylneadipate-co-terephthalate) (PBAT).

A raw material forming vinyl polysiloxane may include the following components in parts by weight: 80-100 parts of divinyldimethicone (a mass fraction of vinyl is 0.05-0.5%, e.g., 0.1%, 0.2%, 0.3%, and 0.4%), 10-25 parts of vinyl silicone resin (a mass fraction of vinyl is 0.1-10%, e.g., 0.5%, 1.0%, 2.0%, 5.0%, 7.0%, and 9.0%), and 2-5 parts of hydromethylsilicone resin as a cross-linked solidification system (a mass fraction of hydrogen is 0.1-6%, e.g., 0.5%, 1.0%, 2.0%, 3.0%, 4.0%, and 5.0%). In addition, trace amounts of platinum catalyst and alkynol inhibitor may be added. After vulcanization, the hardness is approximately shore hardness 30-60 A, and an elongation rate at break is approximately 100-200%. Vinyl polysiloxane is doped with nano-scale inorganic oxide particles, such that the elongation rate at break can be increased. For example, 10-60 parts of nano-silica are added to the raw material described above, such that the elongation rate at break can be increased to 300-600%. Preferably, the nano-silica is gas-phase silica. A particle size may be 5-100 nm, preferably 10-50 nm.

The inventors of the present disclosure found that when one or more stretchable materials A (A1, A2 . . . ) and one or more unstretchable materials B (B1, B2 . . . ) (except an inorganic oxide and a sheet-like material) are mixed in different proportions, or two or more stretchable materials A (A1, A2 . . . ) are mixed in different proportions, at least two main materials are continuously distributed in the regions, showing the following mechanical and physical properties: tensile strength is substantially consistent, elongation rates at break may be significantly different, i.e., at different ratios, forces required by breaks are substantially consistent, but deformations are different under the same tensile force. When multiple main materials are mixed and at least one main material is continuously distributed in the regions and the other main materials are also uniformly distributed, stretch notches, shifts or even breaks are greatly reduced.

In some embodiments of the present disclosure, each region includes polydimethylsiloxane and nanoparticle-doped vinyl polysiloxane. A mass ratio of the raw material of polydimethylsiloxane to the raw material of nanoparticle-doped vinyl polysiloxane may be 1:(0.05-2), e.g., 1:0.1, 1:0.5, 1:1, 1:1.2, 1:1.5, and 1:1.8. The mass ratio between the two raw materials is preferably 1:(0.1-1.5), e.g., 1:0.2, 1:0.5, 1:0.8, 1:1.0, and 1:1.2. Higher content of polydimethylsiloxane indicates a lower elongation rate at break, but tensile strength is substantially the same.

For example, the raw material of polydimethylsiloxane and the raw material of nanoparticle-doped vinyl polysiloxane are mixed based on the mass ratios 1:0.2, 1:0.8, and 1:1.2, to serve as regions S1, S2 and S3 in FIG. 1, respectively. The three mixed materials are solidified and then undergo a tensile break test. FIG. 4 shows results of tensile break tests on stretchable materials formed by the three mixed materials. All tensile strength is approximately 100 kPa. However, elongation rates at break are significantly different. An elongation rate at break of the stretchable material for region S1 is approximately 130%, an elongation rate at break of the stretchable material for regions S2 is approximately 170%, and an elongation rate at break of the stretchable material for region S3 is approximately 235%.

An implementation of the present disclosure is a fabricating method for a stretchable substrate, where the stretchable substrate includes at least two regions having different stretch ratios, where any two adjacent regions having different stretch ratios include at least one same material. The method includes: injecting raw materials for regions having different stretch ratios into corresponding regions in a mold, where mass ratios of one same material contained in the raw materials for the regions having different stretch ratios are different; and solidifying the raw materials of the regions.

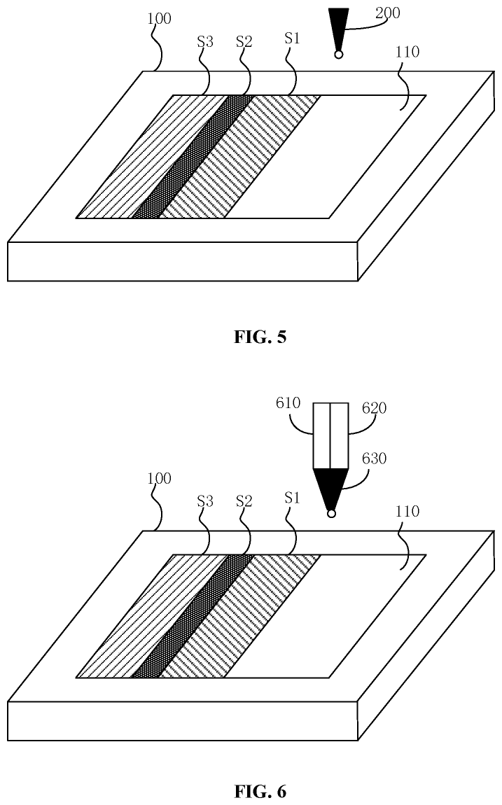

In some embodiments of the present disclosure, the raw materials of the regions may be mixed in advance, and then the raw materials for the regions having different stretch ratios are injected into the corresponding regions in the mold. For example, the raw materials mixed at a preset ratio may be sequentially injected into the corresponding regions in the mold through dispensing or casting and self-leveling. A stretchable material is obtained after the solidification. As shown in FIG. 5, mixed raw materials are injected into a mold cavity 110 of a mold 100 through a dispensing head 200. The raw materials mixed at different raw material ratios may be sequentially injected from one side of the mold cavity to the other side so as to obtain regions having different stretch ratios. In FIG. 5, the different mixed raw materials are sequentially injected from left to right and automatically dispersed. As such, regions S3, S2 and S1 are formed.

To more precisely control sizes and shapes of the regions, before the raw materials for the different regions are injected into the corresponding regions in the mold, partition plates may be disposed between the regions. The partition plates are removed after injection of all the raw materials and before the solidification.

In FIG. 5, one dispensing head 200 is used to inject the raw materials. Alternatively, multiple dispensing heads may be used at the same time to inject the raw materials into the different regions, so that production efficiency is improved.

In addition, in FIG. 5, an open mold is used to inject the raw materials, or the mixed raw materials may be injected into a closed mold cavity. For example, an upper mold and a lower mold may be disposed opposite to each other. The raw materials are injected into a closed mold cavity from one of the molds. Preferably, each region corresponds to one raw material injection head, such that injection of all the raw materials can be completed at a time. Compared with a production mode with an open mold, not only production efficiency can be greatly improved, but also the sheet-like stretchable substrate can become thicker. Moreover, thickness of the regions is more uniform.

In some embodiments of the present disclosure, the raw materials may be mixed during the injection process, rather than being mixed in advance. Therefore, production efficiency can be greatly improved. For example, the raw materials may be injected into the mold through dispensing or injection molding. The different raw materials conveyed by different conveying paths are mixed in a dispensing head or an injection molding head before being injected into the corresponding regions. Taking double components as an example, as shown in FIG. 6, two mixed raw materials may be conveyed respectively through conveying paths 610 and 620 into an injection head 630. The two raw materials are mixed in the injection head 630 before being injected into the corresponding regions. In FIG. 6, volumes of the conveying paths 610 and 620 are the same, and sizes of openings into the injection head 630 are the same. Therefore, conveying pressures on the conveying paths 610 and 620 may be controlled and adjusted to control different raw material ratios.

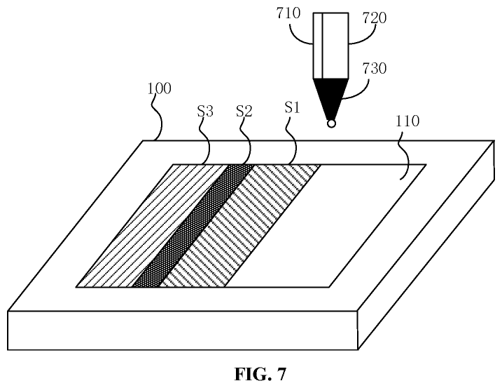

Certainly, volumes of conveying paths may alternatively be different. As shown in FIG. 7, a volume of a conveying path 710 is smaller than that of a conveying path 720, and sizes of openings into an injection head 730 are proportional to the volumes. As such, raw materials at different ratios may be conveyed into the injection head 730 when the same pressure is exerted on the two conveying paths. To sufficiently mix various raw materials in the injection head, the injection head may be provided with a certain length. Moreover, a threaded rod may be disposed in the injection head, so the raw materials are rotated by the threaded rod and sufficiently mixed. In case of three components or more components, each conveying path and injection head may be disposed in a similar way.

In addition, in examples shown in FIG. 6 and FIG. 7, a mold with a closed cavity may alternatively be adopted. Each region may have its independent raw material conveying path and injection head, rather than using only one group of conveying paths and an injection head. Moreover, before the raw materials for the different regions are injected into the corresponding areas in the mold, partition plates may be disposed between the areas. The partition plates are removed after injection of all the raw materials and before the solidification.

### Embodiment 1

In this embodiment, each region included two stretchable materials. One was polydimethylsiloxane, and the other was nanoparticle-doped vinyl polysiloxane. A raw material of polydimethylsiloxane adopted, e.g., Dow Corning 184. A raw material of nanoparticle-doped vinyl polysiloxane adopted: 90 parts of divinyldimethicone (a mass fraction of vinyl was 0.2%), 15 parts of vinyl silicone resin (a mass fraction of vinyl was 5%), 3 parts of hydromethylsilicone resin as a cross-linked solidification system (a mass fraction of hydrogen was 2%), trace amounts of platinum catalyst and alkynol inhibitor, and 10 parts of nano-silica. The raw material of nanoparticle-doped vinyl polysiloxane may be a self-made raw material, or may be a raw material purchased on the market. Dow Corning 184 and the raw material of nanoparticle-doped vinyl polysiloxane were mixed in advance based on the mass ratios 1:0.2, 1:0.8, and 1:1.2, to serve as raw materials for forming regions S1, S2 and S3 in FIG. 1, respectively.

The raw materials mixed in advance were injected into an open mold through dispensing. The stretchable substrate shown in FIG. 1 was formed after solidification.

### Embodiment 2

Different from Embodiment 1, an upper mold and a lower mold were used to inject raw materials into a closed mold cavity to form the stretchable substrate shown in FIG. 1. Compared with Embodiment 1, a sample was neater and more uniform in thickness, and a higher injection pressure may be exerted, thereby increasing production efficiency by 20% or above.

### Embodiment 3

Different from Embodiment 2, a raw material of polydimethylsiloxane and a raw material of nanoparticle-doped vinyl polysiloxane were respectively conveyed by different raw material conveying paths into an injection head, and mixed in the injection head before being injected into a mold cavity for solidification. Compared with Embodiment 1, a sample was neater and more uniform in thickness, and a higher injection pressure may be exerted, thereby increasing production efficiency by 40% or above.

### Embodiment 4

Different from Embodiment 1, Dow Corning 184 and a raw material of nanoparticle-doped vinyl polysiloxane were mixed in advance based on mass ratios 1:0.2 and 1:1.2, to serve as raw materials for forming regions S1 and S3 in FIG. 1. That is, in this embodiment, middle transitional region S2 in FIG. 1 was omitted, and regions S1 and S3 were directly connected to each other.

### Embodiment 5

Different from Embodiment 1, a raw material Dow Corning 184 of polydimethylsiloxane and a raw material of polyurethane were mixed in advance based on mass ratios 1:0.2, 1:0.8, and 1:1.2, to serve as raw materials for forming regions S1, S2, and S3 in FIG. 1, respectively. The raw material of polyurethane adopted a tetrahydrofuran solution of a polyether-MDI (4,4′-diphenylmethane diisocyanate) prepolymer and trimethylolpropane. Polyether-MDI was an isocyanate-terminated PU prepolymer prepared from 4,4′-diphenylmethane diisocyanate and polytetramethylene glycol (molecular weight: 2000) by reaction.

### Embodiment 6

Different from Embodiment 1, a raw material Dow Corning 184 of polydimethylsiloxane and a raw material of SEBS were mixed in advance based on mass ratios 1:0.2, 1:0.8, and 1:1.2, to serve as raw materials for forming regions S1, S2 and S3 in FIG. 1, respectively. The raw material of SEBS adopted, e.g., MP1580M from the TPE branch of Teknor Apex Company.

### Embodiment 7

Different from Embodiment 1, a raw material of vinyl polysiloxane was α,ω-dihydroxy-poly(dimethyl-methylvinyl)siloxane (PDM-MVS) and was mixed with an unstretchable material styrene and a small amount of benzoyl peroxide to form a mixture. Mass ratios of PDM-MVS (vinyl content: 1.5%) to styrene were 1:0.3, 1:0.1, and 1:0.03, which were used to solidify regions S1, S2 and S3 in FIG. 1, respectively.

### Embodiment 8

Different from Embodiment 1, each region included SBS serving as a stretchable material and aluminum oxide serving as an unstretchable material. In parts by weight, 60, 20 and 0 parts of aluminum oxide were separately added to 100 parts of SBS to form regions S1, S2 and S3 in FIG. 1, respectively. An average particle size of aluminum oxide was approximately 100 microns.

### Embodiment 9

Different from Embodiment 4, region S1 was formed with nanoparticle-doped vinyl polysiloxane serving as a stretchable material and sheet-like polystyrene serving as an unstretchable material. In addition, during fabricating, Dow Corning 184 and a raw material of nanoparticle-doped vinyl polysiloxane were injected into region S3 of a mold cavity at a mass ratio 1:1.2. The raw material of nanoparticle-doped vinyl polysiloxane was injected into region S1. Then, polystyrene flakes were added to region S1. Finally, the corresponding raw materials were injected into regions S3 and S1 again, such that the polystyrene flakes were wrapped by the stretchable material.

### Embodiment 10

Different from Embodiment 1, Dow Corning 184 and a raw material of nanoparticle-doped vinyl polysiloxane were mixed in advance based on mass ratios 1:0.2, 1:0.8, and 1:1.2, to serve as raw materials for forming regions S1, S2 and S3 in FIG. 3, respectively.

### Sample Test:

The methods in the embodiments were used to prepare 100 samples (length: 100 mm; width: 20 mm; thickness: 1 mm) Each sample was stretched to the maximum deformation by 90 kPa and kept for 5 seconds and then released. The stretch and release actions were repeated 1000 times. The samples were observed to determine whether notches, shifts, breaks or other defects existed between the regions, and count a sample integrity rate.

In addition, an existing partially stretchable substrate and a circuit stretchable substrate were tested and used as comparative example 1 and comparative example 2, respectively.

| SN | Sample integrity rate |
|---|---|
| Embodiment 1 | 99% |
| Embodiment 2 | 100% |
| Embodiment 3 | 100% |
| Embodiment 4 | 85% |
| Embodiment 5 | 92% |
| Embodiment 6 | 96% |
| Embodiment 7 | 89% |
| Embodiment 8 | 95% |
| Embodiment 9 | 80% |
| Embodiment 10 | 100% |
| Comparative example 1 | 70% |
| Comparative example 2 | 48% |

The above descriptions are merely specific embodiments of the present disclosure, and are not intended to limit the protection scope of the present disclosure. The modifications or replacements readily figured out by a person skilled in the art within the technical scope disclosed in the present disclosure should all fall within the protection scope of the present disclosure.

What is claimed is:

1. A stretchable substrate, comprising at least two regions having different stretch ratios, wherein any two adjacent regions having different stretch ratios comprise at least one same material.

2. The stretchable substrate according to claim 1, wherein the same material is continuously distributed in the regions having different stretch ratios.

3. The stretchable substrate according to claim 1, wherein the same material is continuously distributed at a boundary between the adjacent regions having different stretch ratios.

4. The stretchable substrate according to claim 1, wherein the regions having different stretch ratios are consistent in tensile strength.

5. The stretchable substrate according to claim 1, wherein the same material has different weight proportions in the two adjacent regions having different stretch ratios.

6. The stretchable substrate according to claim 1, wherein the stretchable substrate comprises a first material and a second material, and the first material and the second material are mixed in the regions having different stretch ratios.

7. The stretchable substrate according to claim 6, wherein in the regions having different stretch ratios, a higher weight proportion of the first material indicates a lower weight proportion of the second material.

8. The stretchable substrate according to claim 6, wherein the first material is a stretchable material, and the second material is an unstretchable material.

9. The stretchable substrate according to claim 6, wherein the first material is a first stretchable material, the second material is a second stretchable material, and stretch ratios of the first stretchable material and the second stretchable material are different.

10. The stretchable substrate according to claim 9, wherein the first stretchable material is selected from at least one of vinyl polysiloxane and polydimethylsiloxane, a main chain of the vinyl polysiloxane is a silicon-oxygen chain, and a side chain of the vinyl polysiloxane has a vinyl group and/or a vinyl group-terminated polymer.

11. The stretchable substrate according to claim 9, wherein the second stretchable material is selected from at least one of polyurethane, a styrene-butadiene-styrene block copolymer, a styrene-ethylene-butene-styrene block copolymer, poly(butylneadipate-co-terephthalate) and nanoparticle-doped vinyl polysiloxane, a main chain of the vinyl polysiloxane is a silicon-oxygen chain, and a side chain of the vinyl polysiloxane has a vinyl group and/or a vinyl group-terminated polymer.

12. The stretchable substrate according to claim 9, wherein the first stretchable material is polydimethylsiloxane, the second stretchable material is nanoparticle-doped vinyl polysiloxane, a main chain of the vinyl polysiloxane is a silicon-oxygen chain, and a side chain of the vinyl polysiloxane has a vinyl group and/or a vinyl group-terminated polymer; and
a mass ratio of a raw material of polydimethylsiloxane to a raw material of nanoparticle-doped vinyl polysiloxane is 1:(0.05-2).

13. The stretchable substrate according to claim 1, wherein the stretchable substrate is a one-dimensional stepped stretchable material, and the regions having different stretch ratios are symmetrically distributed on two sides of a region having the highest or lowest stretch ratio.

14. The stretchable substrate according to claim 13, wherein stretch ratios of other regions gradually decrease from the region having the highest stretch ratio to two sides, or stretch ratios of other regions gradually increase from the region having the lowest stretch ratio to two sides.

15. The stretchable substrate according to claim 1, wherein the stretchable substrate is a two-dimensional stepped stretchable material, and a region having a lower stretch ratio is surrounded by a region having a higher stretch ratio.

16. The stretchable substrate according to claim 1, wherein at least one of the regions having different stretch ratios comprises an unstretchable material;
the unstretchable material is selected from inorganic oxide particles; and
the inorganic oxide is selected from at least one of silicon dioxide, aluminum oxide, hafnia, zirconium dioxide, titanium dioxide and calcium oxide.

17. The stretchable substrate according to claim 16, wherein the unstretchable material is a sheet-like material, and the sheet-like material is wrapped by stretchable material.

18. A fabricating method for a stretchable substrate, wherein the stretchable substrate comprises at least two regions having different stretch ratios, wherein any two adjacent regions having different stretch ratios comprise at least one same material, and the method comprises:
mixing the raw materials for each of the regions separately in advance;
injecting raw materials for regions having different stretch ratios into corresponding regions in a mold, where mass ratios of one same material contained in the raw materials for the regions having different stretch ratios are different; and
solidifying the raw materials in each of the regions.

19. The fabricating method for a stretchable substrate according to claim 18, wherein different pressures are exerted on the different conveying paths or inner diameters of the different conveying paths are different.

20. The fabricating method for a stretchable substrate according to claim 18, wherein before the raw materials for the different regions are injected into the corresponding regions in the mold, partition plates are disposed between the regions, and the partition plates are removed after the injection of all the raw materials and before the solidification.
